(19) United States
(12) Patent Application Publication
(10) Pub. No.: US 2025/0344330 A1
(43) Pub. Date: Nov. 6, 2025

(54) COMMUNICATION SYSTEM ENCLOSURE WITH A MOVABLE COMPONENT ATTACHMENT PORTION CONFIGURED TO PROVIDE ENHANCED ACCESS TO COMPONENTS

(71) Applicant: PPC BROADBAND, INC., East Syracuse, NY (US)

(72) Inventor: Gilibaldo RUIZ, Laguna Vista, TX (US)

(73) Assignee: PPC BROADBAND, INC., East Syracuse, NY (US)

(21) Appl. No.: 19/196,816

(22) Filed: May 2, 2025

Related U.S. Application Data
(60) Provisional application No. 63/641,718, filed on May 2, 2024.

(51) Int. Cl. H05K 5/02

(52) U.S. Cl. CPC H05K 5/0247; H05K 5/0256

(57) ABSTRACT

A communication system enclosure structurally configured to provide enhanced access to a communication system component housed in the enclosure for repair and/or replacement. The communication system enclosure may include a housing portion, a component attachment portion structurally configured to support a communication system component within the housing portion, and a mounting portion structurally configured to provide for the component attachment portion to move between a first position where the component attachment portion is positioned within the housing portion and a second position in which the at least a portion of the component attachment portion extends out of the housing portion.

### CROSS REFERENCE TO RELATED APPLICATION

This application claims the benefit of U.S. Provisional Application No. 63/641,718 filed May 2, 2024, which is currently pending, the disclosure of which is hereby incorporated by reference herein in its entirety.

### TECHNICAL FIELD

The present disclosure relates generally to communication system enclosures, and more particularly to a communication system enclosure having one or more movable component attachment portions.

### BACKGROUND

Communication systems and networks (e.g., fiber optic networks) use enclosures to house system components (e.g., equipment and cable). System components within the enclosures are configured to handle different connectivity solutions (e.g., looped cable storage, splicing, and patching). Current enclosure designs have equipment or fiber connectivity mounted inside the enclosure on a static rear wall or pivot panel. In some applications, the space inside the enclosure can be crowded, thus making repairs, upgrades, and growth difficult due to the inability to easily access the equipment and cable.

For example, due to the continuously expanding need for greater fiber density in an enclosure and the desire for minimizing enclosure size, the interior space of the enclosure may be congested. As a result, a technician may have difficulty accessing fibers, connectors, and/or components in the enclosure. Such a congested enclosure also presents the risk that active components and/or connectivity may be disturbed by the technician. Thus, there is a need for an enclosure design that allows for more convenient access to components being housed by the enclosure.

Accordingly, it may be desirable to provide a communication system enclosure that is structurally configured to selectively move mounted components outside of the enclosure for enhanced access by a technician or other user.

### SUMMARY

The present disclosure provides a communication system enclosure structurally configured to provide enhanced access to a communication system component housed in the enclosure for repair and/or replacement.

In some embodiments, the communication system enclosure may include a housing portion, a component attachment portion structurally configured to support a communication system component within the housing portion, and a mounting portion structurally configured to provide for the component attachment portion to move between a first position where the component attachment portion is positioned within the housing portion and a second position in which the at least a portion of the component attachment portion extends out of the housing portion.

In some embodiments, the mounting portion may be structurally configured to mount the component attachment portion vertically within the housing portion and allow the component attachment portion to mount in one of a plurality of alterative lateral positions.

In some embodiments, the component attachment portion and the communication system component attached thereto may be structurally configured to be moved from the first position to the second position so as to provide enhanced access to the communication system component attached for repair or replacement.

In some embodiments, the communication system enclosure may include a second component attachment portion structurally configured to support a second communication system component.

In some embodiments, the mounting portion may be structurally configured to provide for the second component attachment portion to move between a third position where the second component attachment portion is within the housing portion and a fourth position in which at least a portion of the second component attachment portion extends out of the housing portion.

In some embodiments, the mounting portion may be structurally configured to mount the second component attachment portion vertically within the housing portion and allow the second component attachment portion to mount in one of the plurality of alterative lateral positions.

In some embodiments, the component attachment portion may be structurally configured to axially translate between the first position and the second position.

In some embodiments, the component attachment portion may include a first component attachment surface e portion structurally configured to support a communication system component. In some embodiments, the first component attachment surface portion may face laterally relative to the housing portion.

In some embodiments, the component attachment portion may include a cable clearance portion structurally configured to prevent pinching of a communication cable connected to the communication system component when the component attachment portion moves between the first position and the second position.

In some embodiments, the cable clearance portion may include a cut-out portion at a rear portion of the component attachment portion.

In some embodiments, the mounting portion may be configured to support the component attachment portion at both a top end portion and a bottom end portion of the component attachment portion.

In some embodiments, the mounting portion may be structurally configured to provide a plurality of alterative attachment points spaced apart laterally along a back wall portion of the housing portion.

In some embodiments, the mounting portion may include a first support portion structurally configured to support the component attachment portion at a top end portion of the component attachment portion and a second support portion structurally configured to support the component attachment portion at a bottom end portion of the component attachment portion.

In some embodiments, the mounting portion may include a first connecting portion and a second connecting portion structurally configured to allow the component attachment portion to mount in one of a plurality of alterative lateral positions along a back wall portion of the housing portion.

In some embodiments, a communication system enclosure may include a housing portion defining an interior space, a component attachment portion structurally configured to support a communication system component within the interior space, and a mounting portion positioned within the interior space and structurally configured to mount the component attachment portion such that the component attachment portion can axially translate between a first position where the component attachment portion is positioned within the interior space and a second position in which the at least a portion of the component attachment portion extends out of the interior space.

In some embodiments, the mounting portion may include a first support portion structurally configured to support the component attachment portion at a top end portion of the component attachment portion and a second support portion structurally configured to support the component attachment portion at a bottom end portion of the component attachment portion.

In some embodiments, the mounting portion may be structurally configured to mount the component attachment portion vertically within the interior space.

In some embodiments, the mounting portion may include a first connecting portion and a second connecting portion structurally configured to allow the component attachment portion to mount in one of a plurality of alterative lateral positions along a back wall portion of the housing portion.

In some embodiments, the attachment portion may include a cut-out portion at a rear portion of the component attachment portion. In some embodiments, the cut-out portion may be structurally configured to prevent pinching of a communication cable connected to the communication system component when the component attachment portion moves between the first position and the second position.

In some embodiments, the component attachment portion and the communication system component attached thereto may be configured to be moved to the second position so as to provide enhanced access to the communication system component attached for repair and/or replacement relative to the first position.

In some embodiments, the communication system enclosure may include a second component attachment portion structurally configured to support a second communication system component. In some embodiments, the mounting portion may be structurally configured to mount the second component attachment portion such that the second component attachment portion is movable between a third position where the second component attachment portion is within the housing portion and a fourth position in which at least a portion of the second component attachment portion extends out of the housing portion.

In some embodiments, the second component attachment portion may axially translate between the third position and the fourth position.

In some embodiments, the mounting portion may be structurally configured to mount the second component attachment portion vertically spaced apart from the component attachment portion.

In some embodiments, the mounting portion may be structurally configured to mount the second component attachment portion at a plurality of alternate lateral positions.

In some embodiments, the component attachment portion may include a first component attachment surface portion structurally configured to support the communication system component and the second component attachment portion may include a second component attachment surface portion structurally configured to support the second communication system component. In some embodiments, the second component attachment surface portion may face laterally in a direction opposite the first component attachment surface portion.

In some embodiments, a communication system enclosure may include a housing portion defining an interior space, a component attachment portion structurally configured to support a communication system component within the interior space, and a mounting portion positioned within the interior space and structurally configured to mount the component attachment portion such that the component attachment portion is movable between a first position where the component attachment portion is positioned within the interior space and a second position in which the at least a portion of the component attachment portion extends out of the interior space.

In some embodiments, the mounting portion may be structurally configured to mount the component attachment portion vertically within the interior space and allow the component attachment portion to mount in one of a plurality of alterative lateral positions.

In some embodiments, the component attachment portion may include a cable clearance portion structurally configured to prevent pinching of a communication cable connected to the communication system component when the component attachment portion moves between the first position and the second position.

In some embodiments, the component attachment portion and the communication system component attached thereto may be configured to be moved from the first position to the second position so as to provide enhanced access to the communication system component attached for repair or replacement.

In some embodiments, the communication system enclosure may include a second component attachment portion structurally configured to support a second communication system component. In some embodiments, the mounting portion may be structurally configured to provide for the second component attachment portion to move between a third position where the second component attachment portion is within the interior space and a fourth position in which at least a portion of the second component attachment portion extends out of interior space.

In some embodiments, the mounting portion may be structurally configured to mount the second component attachment portion vertically within the interior space and allow the second component attachment portion to mount in one of the plurality of alterative lateral positions.

In some embodiments, the component attachment portion may include a first component attachment surface portion structurally configured to support the communication system component and the second component attachment portion may include a second component attachment surface portion structurally configured to support the second communication system component. In some embodiments, the second component attachment surface portion may face laterally in a direction opposite the first component attachment surface portion.

In some embodiments, the cable clearance portion may include a cut-out portion at a rear portion of the component attachment portion.

In some embodiments, the mounting portion may be structurally configured to support the component attachment portion at both a top end portion and a bottom end portion of the component attachment portion.

In some embodiments, the mounting portion may be structurally configured to provide a plurality of alterative attachment points spaced apart laterally along a back wall portion of the housing portion.

In some embodiments, the mounting portion may include a first support portion structurally configured to support the component attachment portion at a top end portion of the component attachment portion and a second support portion structurally configured to support the component attachment portion at a bottom end portion of the component attachment portion.

Various aspects of the system, as well as other embodiments, objects, features and advantages of this disclosure, will be apparent from the following detailed description of illustrative embodiments thereof, which is to be read in conjunction with the accompanying drawings.

### BRIEF DESCRIPTION OF THE DRAWINGS

The accompanying drawings, which are incorporated in and constitute a part of this specification, illustrate embodiments of the present teachings and together with the description, serve to explain the principles of the present teachings.

FIG. 1 is a perspective view of an example enclosure in accordance with various aspects of the disclosure with a first component attachment portion in a first position.

FIG. 2 is a front view of the enclosure of FIG. 1 with the first component attachment portion in the first position.

FIG. 3 is a perspective view of the enclosure of FIG. 1 with the first component attachment portion in a second position.

FIG. 4. is a perspective view of the enclosure of FIG. 1 with the walls of the enclosure transparent to illustrate a mounting portion of the enclosure.

FIG. 5 is a perspective view of the mounting portion of FIG. 4.

FIG. 6 is a side view of the first component attachment portion in the first position.

FIG. 7 is a side view of the first component attachment portion in the second position.

FIG. 8 is a side view of a second component attachment portion in a third position.

FIG. 9 is a side view of the second component attachment portion of FIG. 8 in a fourth position.

### DETAILED DESCRIPTION

Reference will now be made in detail to presently preferred embodiments and methods of the present disclosure, which constitute the best modes of practicing the present disclosure presently known to the inventors. The figures are not necessarily to scale. It is to be understood, however, that the disclosed embodiments are merely exemplary of the present disclosure that may be embodied in various and alternative forms. Therefore, specific details disclosed herein are not to be interpreted as limiting, but merely as a representative basis for any aspect of the present disclosure and/or as a representative basis for teaching one skilled in the art to variously employ the present disclosure.

It is also to be understood that this present disclosure is not limited to the specific embodiments and methods described below, as specific components and/or conditions may, of course, vary. Furthermore, the terminology used herein is used only for the purpose of describing particular embodiments of the present disclosure and is not intended to be limiting in any way.

It must also be noted that, as used in the specification and the appended claims, the singular form “a,” “an,” and “the” comprise plural referents unless the context clearly indicates otherwise. For example, reference to a component in the singular is intended to comprise a plurality of components.

Embodiments of the disclosure provide a communication system enclosure 10 for providing connectivity solutions (e.g., looped cable storage, splicing, and patching) for communication cable, such as fiber optic cable, copper coaxial cable, etc. The communication system enclosure 10 may be structurally configured to house communication system components (e.g., equipment, cable. etc.) and provide convenient access to the communication system components. For example, in some implementations, the communication system enclosure 10 may be structurally configured to move the communication system components to a position that provide easy access (e.g., a position external to the enclosure).

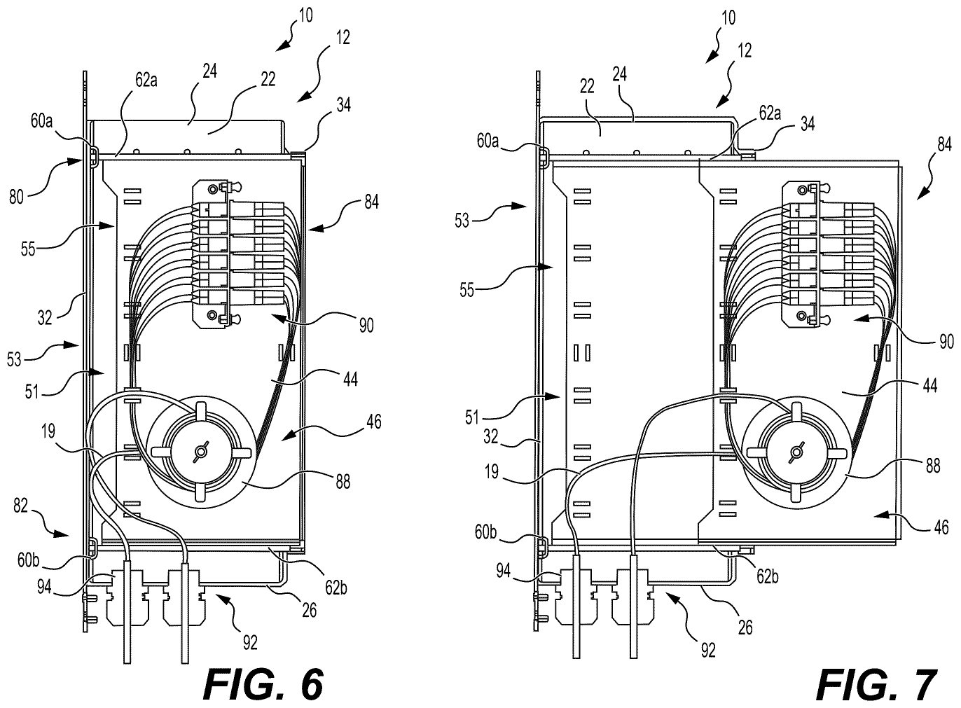

In some implementations, the communication system enclosure 10 may include a housing portion 12, a mounting portion 14, and a component attachment portion 16. The housing portion 12 may be structurally configured to house a communication system component portion 18 (e.g., communication system components such as a patch panel, splice box, cable management components, etc.) and a communication cable 19 (e.g., communication cables such as a fiber optic cable, copper coaxial cable, etc.) (FIGS. 6-9) connected to the communication system component portion 18. The housing portion 12 may be configured in a variety of ways.

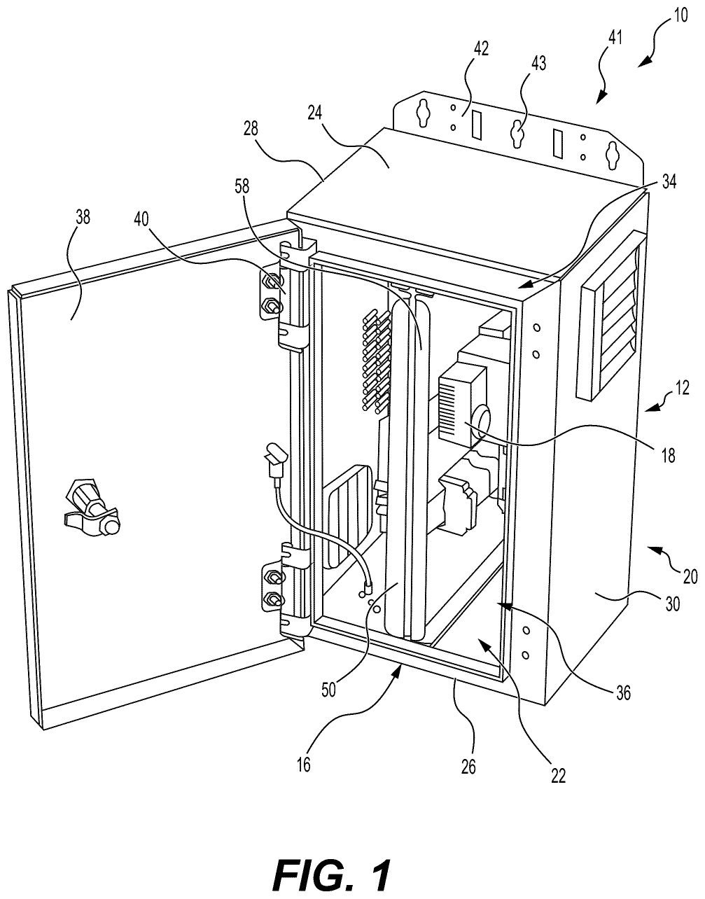

The housing portion 12 may be configured in a variety of ways, including, but limited to, size, shape, and materials used. Referring to FIGS. 1-4, in some implementations, the housing portion 12 may include a wall portion 20, for example, a plurality of walls, defining an interior space 22. For example, in some implementations, the housing portion 12 may include top wall portion 24, a bottom wall portion 26 opposite the top wall portion 24, a first side wall portion 28 extending between the top wall portion 24 and the bottom wall portion 26, a second side wall portion 30 opposite the first side wall portion 28 and extending between the top wall portion 24 and the bottom wall portion 26, and a rear wall portion 32 (FIGS. 6-9) extending between the top wall portion 24 and the bottom wall portion 26. In some implementations, the housing portion 12 may be generally cuboid-shaped.

In some implementations, the housing portion 12 may include a forward edge portion 34 defined by the top wall portion 24, the bottom wall portion 26, the first side wall portion 28, and the second side wall portion 30. The forward edge portion 34 may define a receiving portion 36, for example, an opening to the interior space 22. In some implementations, the housing portion 12 may include a closure or closure portion 38 (e.g., a door, a lid, a cover, etc.) structurally configured to cover the receiving portion 36 to the interior space 22. In some implementations, the closure portion 38 may be movable between a closed position in which the closure portion 38 covers the receiving portion 36 and an open position in which the receiving portion 36 is uncovered (at least partially) (FIG. 1). The closure portion 38 may structurally configured to move between the closed position and the open position in a variety of ways. In some implementations, the closure portion 38 may be attached to, or proximate to, the forward edge portion 34 by a hinge connection 40 such that the closure portion 38 may pivot between the open and closed position.

In some implementations, the communication system enclosure 10 may include an enclosure mounting portion 41 (FIG. 1) structurally configured to provide a means for mounting the communication system enclosure 10 to a mounting surface (e.g., wall, pole, etc.) (not shown). The enclosure mounting portion 41 may be configured in a variety of ways. In some implementations, the enclosure mounting portion 41 may include a flange 42 having one or more openings 43 structurally configured to receive one or more fasteners (e.g., screws, nails, bolts, etc.) (not shown) for mounting the communication system enclosure 10 to a mounting surface.

The component attachment portion 16 may be structurally configured to support one or more communication system component portions 18 within the housing portion 12. The component attachment portion 16 may be configured in a variety of ways. For example, in some implementations, the component attachment portion 16 may include a first component attachment surface 44 structurally configured for the one or more communication system component portions 18 to mount thereto. For example, in some implementations, the component attachment portion 16 may include a first face 46 and a second face 48 opposite the first face 46. In some implementations, the component attachment portion 16 may include a first panel-shaped (e.g., generally thin and flat) portion 50 where the first face 46 and the second face 48 are major faces of the first panel-shaped portion 50. In some implementations, the first face 46 may include the first component attachment surface 44.

In some implementations, the first panel-shaped portion 50 may include perforations (not shown) to allow for ventilation. In some implementations, the first panel-shaped portion 50 may include a cable clearance portion 51 structurally configured to provide space for routing the communication cables 19 extending from communication system component portions 18 supported by the first panel-shaped portion 50 within the interior space without obstructing movement of the first panel-shaped portion 50 or pinching of the communication cables 19. In some embodiments, the cable clearance portion 51 may be positioned at a rear portion 53 of the first panel-shaped portion 50 (i.e., adjacent the rear wall portion 32 of the enclosure when the first panel-shaped portion 50 is fully received within the housing portion 12. In some embodiments, the cable clearance portion 51 may be a cut-out or recessed portion 55 on the first panel-shaped portion 50.

The component attachment portion 16 may be structurally configured to support the one or more communication system component portions 18 in a variety of ways. For example, in some implementations, the one or more communication system component potions 18 may mount onto the component attachment portion 16 (e.g., onto the first component attachment surface 44). The one or more communication system component portions 18 may mount to the component attachment portion 16 in any suitable manner, such as with fasteners, for example.

In some implementations, the component attachment portion 16 may include a second component attachment surface 52 structurally configured for the one or more communication system component portions 18 to mount thereto. For example, in some implementations, the component attachment portion 16 may include a third face 54 and a fourth face 56 opposite the third face 54. In some implementations, the component attachment portion 16 may include a second panel-shaped (e.g., generally thin and flat) portion 58 where the third face 54 and the fourth face 56 are major faces of the second panel-shaped portion 58. In some implementations, the third face 54 may include the second component attachment surface 52.

The mounting portion 14 may be structurally configured to support the component attachment portion 16 within the housing portion 12. In some implementations the mounting portion 14 may be structurally configured to support the component attachment portion 16 such that the component attachment portion 16 may be movable between a first position where the component attachment portion 16 may be positioned within the interior space 22 of the housing portion 12 and a second position in which at least a portion of the component attachment portion 16 may be exterior to the interior space 22. For example, in some implementations, the entire component attachment portion 16 may be within the interior space 22 in the first position. In other implementations, less than the entire component attachment portion 16 may be within the interior space 22 when in the first position. In some implementations, at least a portion (e.g., a majority) of the component attachment portion 16 may be exterior to the interior space 22 in the second position. For example, in some implementations, at least 60%, at least 70%, or at least 80% of the component attachment portion 16 may be exterior to the interior space in the second position.

In some implementations, the mounting portion 14 may be structurally configured to support the component attachment portion 16 in a fixed vertical orientation (i.e., the component attachment portion remains in the same vertical orientation in both the first position and the second position). In other embodiments, however, the mounting portion 14 may be structurally configured to support the component attachment portion 16 other than in a fixed vertical orientation (e.g., a horizontal orientation). In some embodiments, the housing portion 12 may be configured to be pole-mounted.

The mounting portion 14 may be configured in a variety of ways, including, but not limited to, how the mounting portion 14 supports the component attachment portion 16 and how the mounting portion 14 allows movement of the component attachment portion 16 between the first position and the second position. In some implementations, the mounting portion 14 may be structurally configured to allow the component attachment portion 16 to axially translate (e.g., slide) between the first position and the second position. For example, in some implementations, the mounting portion 14 may utilize slide guides, drawer slides, card guides, doubles lances, or other configurations that allow the component attachment portion 16 to axially translate.

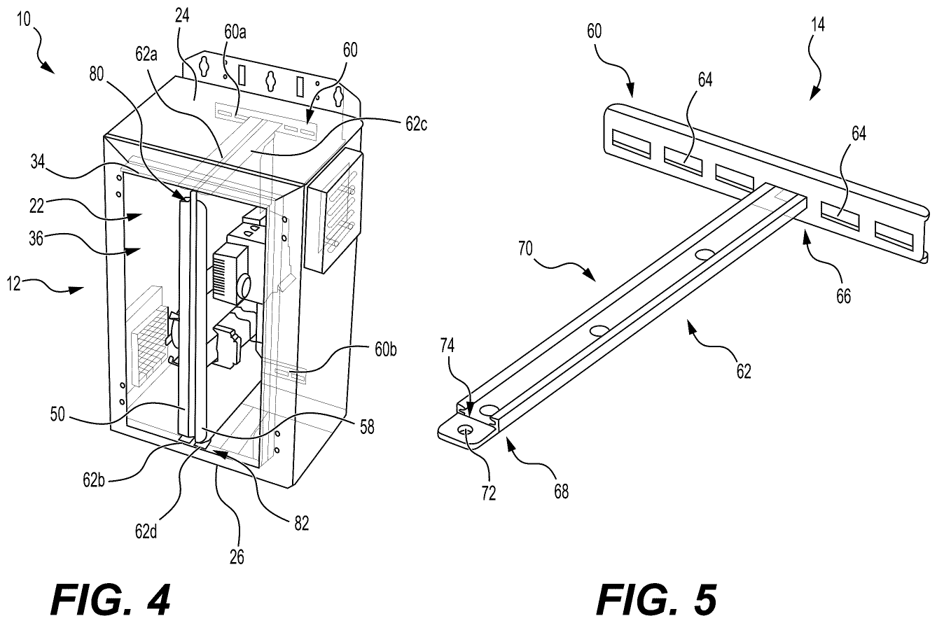

Referring to FIGS. 4-5, in some implementations, the mounting portion 14 may include a connection portion 60 and a support portion 62 connected to the connection portion 60. The connection portion 60 may be configured in a variety of ways. In some implementations, the connection portion 60 may be structurally configured to attach to the housing portion 12 within the interior space 22. For example, in some implementations, the connection portion 60 may be structurally configured to mount to one or more of the top wall portion 24, the bottom wall portion 26, the first side wall portion 28, the second side wall portion 30, and the rear wall portion 32. In the illustrated implementation, the connection portion 60 may be attached to the rear wall portion 32. The connection portion 60 may mount to the housing portion 12 in any suitable way, such as for example, one or more fasteners (now shown).

In some implementations, the connection portion 60 may be structurally configured to provide a plurality of alternative attachment points 64 for the support portion 62 to attach to the connection portion 60. For example, in some implementations, the connection portion 60 may be structurally configured such that the alternative attachment points 64 allow the support portion 62 to be arranged in one or plurality of lateral positions (i.e., between the first side wall portion 28 and the second side wall portions 30). In some implementations, the connection portion 60 may have an elongated shape (e.g., rail, bracket, etc.) and may be mounted lengthwise along the rear wall portion 32 (e.g., parallel with the bottom wall portion 26).

The support portion 62 may be structurally configured to attach the connection portion 60 to support the component attachment portion 16 within the interior space 22. The support portion 62 may be structurally configured to engage with component attachment portion 16 to allow movement of the component attachment portion 16 between the first position and the second position while being supported. The support portion 62 may be configured in a variety of ways. In some implementations, the support portion 62 has a first end portion 66, a second end portion 68 opposite the first end portion 66 and an elongated portion 70 extending between the first end portion 66 to a second end portion 68.

The first end portion 66 may be structurally configured to attach to the connection portion 60. The first end portion 66 may be structurally configured to attach to the connection portion 60 in a variety of ways. In some implementations, the first end portion 66 may be received in one of the attachment points 64, or otherwise engaged with one of the attachment points 64, such that the connection portion 60 supports the first end portion 66. The second end portion 68 may be structurally configured to be supported at, or adjacent, the forward edge portion 34. For example, in some implementations, the second end portion 68 may include one or more openings 72 structurally configured to receive a fastener (e.g., screw, bolt, etc.) to connect the second end portion 68 to, or adjacent, the forward edge portion 34.

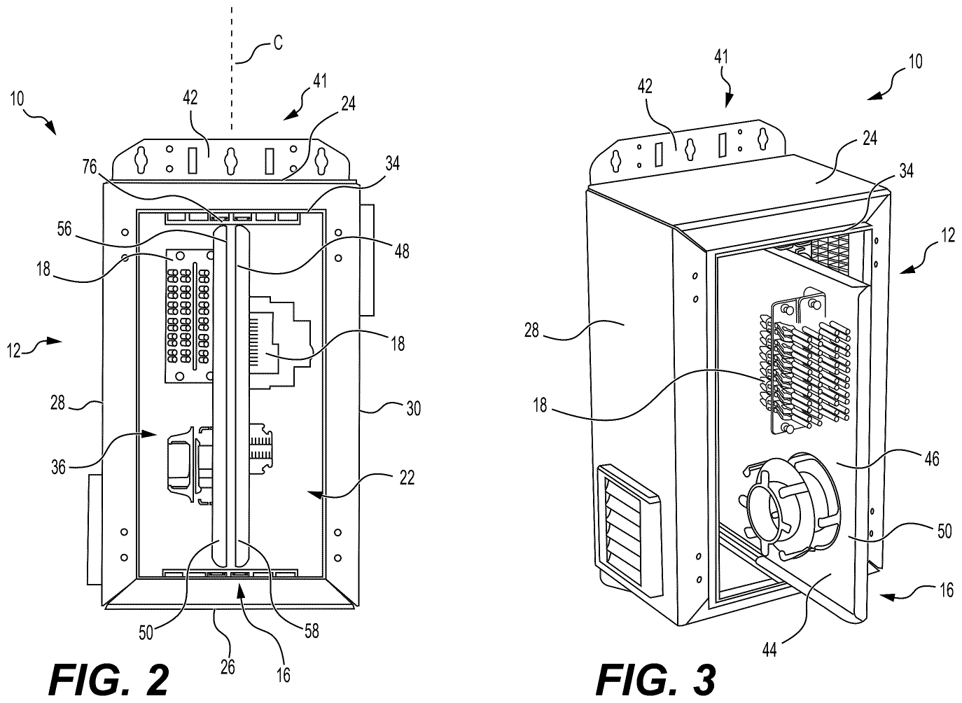

The elongated portion 70 may be structurally configured to retain the component attachment portion 16 while allowing the component attachment portion 16 to move between the first position and the second position. The elongated portion 70 may be configured in a variety of ways. In some implementations, the elongated portion 70 may be structurally configured to allow the component attachment portion 16 to axially translate (e.g., slide) between the first position and the second position. For example, in some implementations, the elongated portion 70 may include a T-shaped channel 74 (FIG. 5) structurally configured to receive a T-shaped extension 76 (FIG. 2) such that the component attachment portion 16 may be held in the T-shaped channel 74 while being able to slide along the T-shaped channel 74.

In some implementations, the component attachment portion 16 may include a plurality of component attachment surfaces (e.g., the first component attachment surface 44 and the second component attachment surface 52). The plurality of component attachment surfaces may be arranged within the housing portion 12 in any suitable manner (e.g., vertically, horizontally, etc.). In some implementations, the first component attachment surface 44 and the second component attachment surface 52 may face in opposite directions. For example, in some implementations, the component attachment portion 16 may be structurally configured such that the first component attachment surface 44 faces laterally toward the toward the first side wall portion 28 and the second component attachment surface 52 faces laterally toward the second side wall portion 30.

In some implementations, the component attachment portion 16 may be supported at both a top end portion 80 and a bottom end portion 82 of the component attachment portion 16 (FIG. 4). For example, in some implementations, the mounting portion 14 may include a first connecting portion 60a and a first support portion 62a mounted near or adjacent the top wall portion 24 and a second connecting portion 60b and a second support portion 62b mounted near or adjacent the bottom wall portion 26. Thus, the first connecting portion 60a and first support portion 62a may support the component attachment portion 16 at the top end portion 80 and the second connecting portion 60b and the second support portion 62b may support the component attachment portion 16 at the bottom end portion 82. The first connecting portion 60a and the second connecting portion 60b may be configured the same as the connecting portion 60 and the first support portion 62a and the second support portion 62b may be configured the same as the support portion 62.

In some implementations, the component attachment portion 16 may include the first panel-shaped portion 50 and the second panel-shaped portion 58. In some implementations, the first panel-shaped portion 50 may be supported by the first connecting portion 60a, the first support portion 62a, the second connecting portion 60b, and the second support portion 62b. In some implementations, the first panel-shaped portion 50 may be moveable between the first position where the first panel-shaped portion 50 may be positioned within the housing portion 12 and the second position where the first panel-shaped portion 50 may at least partially extend out of the housing portion 12. In some implementations, at least a portion (e.g., a majority) of the first panel-shaped portion 50 may be exterior to the interior space 22 in the second position. For example, in some implementations, at least 60%, at least 70%, or at least 80% of the first panel-shaped portion 50 may be exterior to the interior space 22 in the second position.

In some implementations, the second panel-shaped portion 58 may be supported by the first connecting portion 60a, a third support portion 62c, the second connecting portion 60b, and the fourth support portion 62d. The third support portion 62c may be structurally configured and attached to the first connecting portion 60a in the same manner as the first support portion 62a and the fourth support portion 62d may be structurally configured and attached to the second connecting portion 60b in the same manner as the second support portion 62b.

In some implementations, the second panel-shaped portion 58 may be moveable between the first position where the second panel-shaped portion 58 may be positioned within the housing portion 12 and the second position where the second panel-shaped portion 58 may at least partially extend out of the housing portion 12. In some implementations, at least a portion (e.g., a majority) of the second panel-shaped portion 58 may be exterior to the interior space 22 in the second position. For example, in some implementations, at least 60%, at least 70%, or at least 80% of the second panel-shaped portion 58 may be exterior to the interior space 22 in the second position.

In some implementations, the first panel-shaped portion 50 and the second panel-shaped portion 58 may be movable between the first position and the second position independent of one another. In some implementations, the first panel-shaped portion 50 and the second panel-shaped portion 58 may be arranged vertically side-by-side to each other at or adjacent a centerline C (FIG. 2) of the interior space 22. The lateral position the first panel-shaped portion 50 and the second panel-shaped portion 58, however, can be adjusted by mounting the first, second, third, and fourth support portions 62a-62d in the alternative attachment points 64 corresponding to the desired lateral position.

In some implementations, the communication system component portions 18 may include one, or both, of fiber optic related components 84 and copper cable related components 86. Any suitable fiber optic related components 84 and/or copper cable related components 86 may be supported by the component attachment portion 16. In some implementations, the first component attachment surface 44 of the first panel-shaped portion 50 may be structurally configured to mount fiber optic related components 84 and the second component attachment surface 52 of the second panel-shaped portion 58 may be structurally configured to mount copper cable related components 86. For example, in some implementations, the fiber optic related components 84 mounted to the first component attachment surface 44 may include a fiber management portion 88 (e.g., a fiber management spool) and a fiber distribution portion 90 (e.g., a LGX panel (12f, 24f, 48f, etc.) or splice box).

Referring to FIGS. 6-7, the component attachment portion 16 is illustrated in both the first position and in the second position. For example, FIG. 6 illustrates the first component attachment surface 44 with fiber optic related components 84 mounted thereon in the first position. In the first position, the first component attachment surface 44 may be positioned within the housing portion 12. In some implementations, the housing portion 12 may include a cable passage portion 92 structurally configured to route the communication cables 19 into and out of the housing portion 12. The cable passage portion 92 may be configured in a variety of ways. For example, in some implementations, the cable passage portion 92 may include one or more cable glands 94. In some implementations, the cable passage portion 92 may be positioned at, or adjacent, the bottom wall portion 26, such that the communication cables 19 enter and exit the housing portion 12 at, or adjacent, the bottom wall portion 26. In other implementations, the cable passage portion 92 may be configured such that the communication cables 19 enter and/or exit the housing portion 12 other than at, or adjacent, the bottom wall portion 26.

As shown in FIG. 6, when the first component attachment surface 44 is in the first position, the cable clearance portion 51 may provide space that avoids or inhibits pinching of the communication cables 19 or having the communication obstruct movement as the first component attachment surface 44 moves between the first and second positions. As shown in FIG. 7, the first component attachment surface 44 can be moved to the second position such that at least a portion (e.g., a majority) of the component attachment portion extends out of the housing portion 12. For example, the first component attachment surface 44 may axially translate (e.g., slide) to the second position via the first support portion 62a. In the second position, the fiber optic related components 84 and associated communication cables 19 are more accessible for making repairs, upgrades, replacements, and additions.

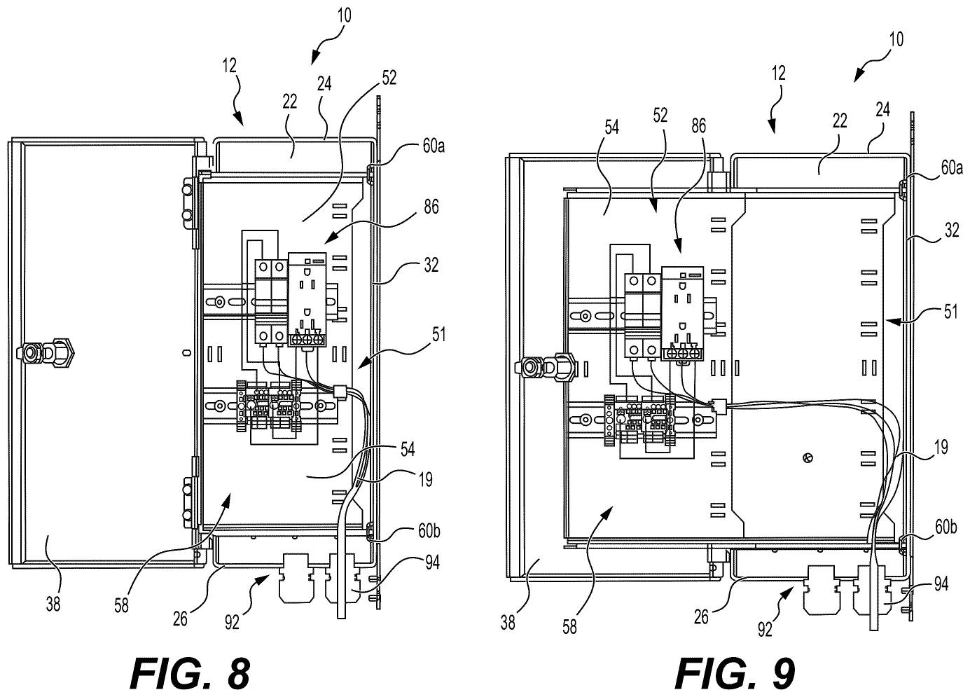

FIG. 8 illustrates the second component attachment surface 52 with copper cable related components 86 mounted thereon in a third position, which is the same, or a similar position, as the first position with respect to the first component attachment surface 44. In the third position, the second component attachment surface 52 may be positioned within the housing portion 12. When the second component attachment surface 52 is in the third position, the cable clearance portion 51 may provide space that avoids or inhibits pinching of the communication cables 19 or having the communication obstruct movement as the second component attachment surface 52 moves between the third and the fourth positions.

As shown in FIG. 9, the second component attachment surface 52 can be moved to a fourth position, which is the same, or a similar position, as the second position with respect to the first component attachment surface 44. In the fourth position, at least a portion (e.g., a majority) of the component attachment portion 16 extends out of the housing portion 12. For example, the second component attachment surface 52 may axially translate (e.g., slide) to the second position via the second support portion 62b. In the second position, the copper cable related components 86 and associated communication cables 19 are more accessible for making repairs, upgrades, replacements, and additions. In some implementations, the first component attachment surface 44 and the second component attachment surface 52 are moveable between the first and second positions independent of each other.

While at least one example, non-limiting embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing the exemplary embodiment or exemplary embodiments. It should be understood that various changes can be made in the function and arrangement of elements without departing from the scope of the disclosure as set forth in the appended claims and the legal equivalents thereof.

What is claimed is:

1. A communication system enclosure structurally configured to provide enhanced access to a communication system component housed in the enclosure for repair and/or replacement comprising:
a housing portion defining an interior space;
a component attachment portion structurally configured to support a communication system component within the interior space;
a mounting portion positioned within the interior space and structurally configured to mount the component attachment portion such that the component attachment portion can axially translate between a first position where the component attachment portion is positioned within the interior space and a second position in which the at least a portion of the component attachment portion extends out of the interior space;
wherein the mounting portion includes a first support portion structurally configured to support the component attachment portion at a top end portion of the component attachment portion and a second support portion structurally configured to support the component attachment portion at a bottom end portion of the component attachment portion;
wherein the mounting portion is structurally configured to mount the component attachment portion vertically within the interior space;
wherein the mounting portion includes a first connecting portion and a second connecting portion structurally configured to allow the component attachment portion to mount in one of a plurality of alterative lateral positions along a back wall portion of the housing portion;
wherein the component attachment portion includes a cut-out portion at a rear portion of the component attachment portion, wherein the cut-out portion is structurally configured to prevent pinching of a communication cable connected to a communication system component when the component attachment portion moves between the first position and the second position; and
wherein the mounting portion is structurally configured to permit the component attachment portion and a communication system component attached thereto to be moved to the second position so as to provide enhanced access to the attached communication system component for repair and/or replacement relative to the first position.

2. The communication system enclosure of claim 1, further comprising:
a second component attachment portion structurally configured to support a second communication system component;
wherein the mounting portion is structurally configured to mount the second component attachment portion such that the second component attachment portion is movable between a third position where the second component attachment portion is within the housing portion and a fourth position in which at least a portion of the second component attachment portion extends out of the housing portion;
wherein the second component attachment portion axially translates between the third position and the fourth position;
wherein the mounting portion is structurally configured to mount the second component attachment portion vertically spaced apart from the component attachment portion; and
wherein the mounting portion is structurally configured to mount the second component attachment portion at a plurality of alternate lateral positions.

3. The communication system enclosure of claim 2, wherein the component attachment portion includes a first component attachment surface portion structurally configured to support the communication system component and the second component attachment portion includes a second component attachment surface portion structurally configured to support the second communication system component, and wherein the second component attachment surface portion faces laterally in a direction opposite the first component attachment surface portion.

4. A communication system enclosure structurally configured to provide enhanced access to a communication system component housed in the enclosure for repair and/or replacement comprising:
a housing portion defining an interior space;
a component attachment portion structurally configured to support a communication system component within the interior space;
a mounting portion positioned within the interior space and structurally configured to mount the component attachment portion such that the component attachment portion is movable between a first position where the component attachment portion is positioned within the interior space and a second position in which the at least a portion of the component attachment portion extends out of the interior space;
wherein the mounting portion is structurally configured to mount the component attachment portion vertically within the interior space and allow the component attachment portion to mount in one of a plurality of alterative lateral positions;
wherein the component attachment portion includes a cable clearance portion structurally configured to prevent pinching of a communication cable connected to a communication system component when the component attachment portion moves between the first position and the second position; and
wherein the mounting portion is structurally configured to permit the component attachment portion and a communication system component attached thereto to be moved from the first position to the second position so as to provide enhanced access to the attached communication system component for repair or replacement.

5. The communication system enclosure of claim 4, further comprising:
a second component attachment portion structurally configured to support a second communication system component;
wherein the mounting portion is structurally configured to provide for the second component attachment portion to move between a third position where the second component attachment portion is within the interior space and a fourth position in which at least a portion of the second component attachment portion extends out of interior space; and
wherein the mounting portion is structurally configured to mount the second component attachment portion vertically within the interior space and allow the second component attachment portion to mount in one of the plurality of alterative lateral positions.

6. The communication system enclosure of claim 5, wherein the component attachment portion includes a first component attachment surface portion structurally configured to support the communication system component and the second component attachment portion includes a second component attachment surface portion structurally configured to support the second communication system component, and wherein the second component attachment surface portion faces laterally in a direction opposite the first component attachment surface portion.

7. The communication system enclosure of claim 4, wherein the cable clearance portion includes a cut-out portion at a rear portion of the component attachment portion.

8. The communication system enclosure of claim 4, wherein the mounting portion is configured to support the component attachment portion at both a top end portion and a bottom end portion of the component attachment portion.

9. The communication system enclosure of claim 4, wherein the mounting portion is structurally configured to provide a plurality of alterative attachment points spaced apart laterally along a back wall portion of the housing portion.

10. The communication system enclosure of claim 4, wherein the mounting portion includes a first support portion structurally configured to support the component attachment portion at a top end portion of the component attachment portion and a second support portion structurally configured to support the component attachment portion at a bottom end portion of the component attachment portion.

11. A communication system enclosure structurally configured to provide enhanced access to a communication system component housed in the enclosure for repair and/or replacement comprising:
a component attachment portion structurally configured to support a communication system component within a housing portion;
a mounting portion structurally configured to permit the component attachment portion to move between a first position where the component attachment portion is positioned within the housing portion and a second position in which the at least a portion of the component attachment portion extends out of the housing portion;
wherein the mounting portion is structurally configured to mount the component attachment portion vertically within the housing portion and allow the component attachment portion to mount in one of a plurality of alterative lateral positions; and
wherein the mounting portion is structurally configured to permit the component attachment portion and a communication system component attached thereto to be moved from the first position to the second position so as to provide enhanced access to the attached communication system component for repair or replacement.

12. The communication system enclosure of claim 11, further comprising:
a second component attachment portion structurally configured to support a second communication system component;
wherein the mounting portion is structurally configured to provide for the second component attachment portion to move between a third position where the second component attachment portion is within the housing portion and a fourth position in which at least a portion of the second component attachment portion extends out of the housing portion; and
wherein the mounting portion is structurally configured to mount the second component attachment portion vertically within the housing portion and allow the second component attachment portion to mount in one of the plurality of alterative lateral positions.

13. The communication system enclosure of claim 11, wherein the component attachment portion is structurally configured to axially translate between the first position and the second position.

14. The communication system enclosure of claim 11, wherein the component attachment portion includes a first component attachment surface portion structurally configured to support a communication system component, and wherein the first component attachment surface portion faces laterally relative to the housing portion.

15. The communication system enclosure of claim 11, wherein the component attachment portion includes a cable clearance portion structurally configured to prevent pinching of a communication cable connected to the communication system component when the component attachment portion moves between the first position and the second position.

16. The communication system enclosure of claim 15, wherein the cable clearance portion includes a cut-out portion at a rear portion of the component attachment portion.

17. The communication system enclosure of claim 11, wherein mounting portion is configured to support the component attachment portion at both a top end portion and a bottom end portion of the component attachment portion.

18. The communication system enclosure of claim 11, wherein the mounting portion is structurally configured to provide a plurality of alterative attachment points spaced apart laterally along a back wall portion of the housing portion.

19. The communication system enclosure of claim 11, wherein the mounting portion includes a first support portion structurally configured to support the component attachment portion at a top end portion of the component attachment portion and a second support portion structurally configured to support the component attachment portion at a bottom end portion of the component attachment portion.

20. The communication system enclosure of claim 11, wherein the mounting portion includes a first connecting portion and a second connecting portion structurally configured to allow the component attachment portion to mount in one of a plurality of alterative lateral positions along a back wall portion of the housing portion.
